(19) United States
(12) Patent Application Publication
(10) Pub. No.: US 2015/0009641 A1
(43) Pub. Date: Jan. 8, 2015

(54) CIRCUIT CARD CONFIGURATION

(71) Applicant: Daniel Sjölund, Örnsköldsvik (SE)

(72) Inventor: Daniel Sjölund, Örnsköldsvik (SE)

(73) Assignee: BAE Systems Hägglunds Aktiebolag, Örnsköldsvik (SE)

(21) Appl. No.: 14/344,595

(22) PCT Filed: Sep. 7, 2012
(86) PCT No.: PCT/SE2012/050949

§ 371 Date: Mar. 12, 2014

(30) Foreign Application Priority Data
Sep. 14, 2011 (SE) 1150831-4

(51) Int. Cl. H01R 12/52; H05K 5/00; H05K 1/18

(52) U.S. Cl. CPC H01R 12/52; H05K 1/18; H05K 5/0047
USPC 361/752

(57) ABSTRACT

The present disclosure relates to a circuit card configuration having a card element arranged to be attached via assembly points and to support connection points for signal connection and ground connection. The respective assembly points as well as the respective connection points each have a metallic bushing arranged to be attached at the card element.

### TECHNICAL FIELD

The invention relates to a circuit card configuration according to the preamble of claim 1.

### BACKGROUND ART

An electric filter is usually made up of a circuit card with incoming and outgoing signals and connection to chassis ground. A problem with such filters by connection of coarse cable clips is that rigid cables result in breaking forces in the circuit card, wherein the laminate of the circuit card breaks due to the forces provided by the tightening torque.

The casing of such a filter shall fulfil high demands on tightness and keep all parts in place during vibrations and impacts. Further it is desired that the filter is connected to chassis ground with low impedance.

There are a number of solutions for cable connection to e.g. screw terminal blocks which are attached along side of the circuit card or stiffening bars of copper distributing the load over the card. The disadvantage is that the casing becomes relatively large in order to house terminal blocks, connectors etc. mostly cast aluminium casing and a Gore-Tex ventilator are used for managing tightness and moisture.

Screw caps or connectors are used to seal around incoming and outgoing signals and an earth braid or the like is then used to connect the circuit card to the chassis. Alternatively the card is grounded through its assembly spacers which results in many contact surfaces with contact resistance.

US2003067751 shows a housing for an electronic control unit for a vehicle with an inner housing in plastic with corner-supporting metallic pin bolts and a metallic outer box. The metallic pin bolts are arranged to be pressed through corresponding openings in a circuit card until a step bears against its surface. Through this technique a mechanically robust and electrically conductive connection between the circuit card and the pin bolts is obtained.

### OBJECTS OF THE INVENTION

An object of the present invention is to provide a circuit card configuration facilitating simplified manufacturing, having few components, being cost efficient, facilitating good ground connection and being environmentally durable.

### SUMMARY OF THE INVENTION

These and other objects, apparent from the following description, are achieved by circuit card configuration which is of the type stated by way of introduction and which in addition exhibits the features recited in the characterising clause of the appended claim 1. Preferred embodiments of the circuit card configuration are defined in appended dependent claims 2-10.

Specifically an object of the invention is achieved by a circuit card configuration comprising a card element being arranged to be attached via assembly points and to support connection points for signal connection and ground connection, wherein the respective assembly points as well as the respective connection points comprise a metallic bushing arranged to be attached at the card element. Hereby only a small number of components are required, no terminal blocks, earth braids, screw caps or connectors are required. The manufacturing hereby becomes simplified. Further uniform manufacturing is facilitated as all bushings can be made alike. In addition cheaper components may be used. Hereby is facilitated, through said connection points, direct connection to ground in e.g. a vehicles chassis wherein low impedance, i.e. low contact resistance is obtained, at the same time as the connection points may constitute assembly points.

According to an embodiment of the circuit card configuration said metallic bushing is essentially made of brass. Hereby good electric contact and solder ability is facilitated.

According to an embodiment of the circuit card configuration said bushing is arranged to be attached to the card element with soldered joints and/or screw joints. Soldered joints results in rational manufacturing of the filter. Soldered joints results in low contact resistance which is not impaired with time. By using screw joint removal of bushing is facilitated. Further a strong joint is facilitated.

According to an embodiment of the circuit card configuration the card element with its bushings is arranged to be embedded in a cast compound. By using a cast compound the bushings are prevented from being turned and where applicable, i.e. where soldered joints are used, protects the soldered seam. Further the cast compound provides stability such that the card element/circuit card configuration withstands load from e.g. rigid cables, vibrations and the like. The cast compound improves the structural strength of the circuit card configuration. Further the environment durability is improved.

According to an embodiment of the circuit card configuration said metallic bushing comprises a portion with a polygonal cross section. Said portion with a polygonal cross section further contributes to preventing turn of bushing when it is arranged in a cast compound.

According to an embodiment of the circuit card configuration said polygon is a regular hexagon. In addition to turn of bushings in cast compound being prevented, screwing of the bushings by means of e.g. an adjustable wrench is also facilitated.

According to an embodiment of the circuit card configuration said metallic bushing comprises an internal thread. Hereby insertion of a screw for attaching a cable clip is facilitated.

According to an embodiment of the circuit card configuration said metallic bushing comprises a through hole for said assembly and/or signal connection. This simplifies assembly and facilitates signal connection. Hereby reduced torsion stress of soldered joints is facilitated by using screw joints with jam nut such that the card element is not used as a holder-on but instead the jam nut.

According to an embodiment of the circuit card configuration said card element and at least parts of said bushings are housed in a box. Hereby structural strength of the circuit card configuration is further improved wherein a more robust construction is obtained. The box, when cast compound is used, keeps the cast compound in place during the hardening process. the box may also be utilised as casting mould and subsequently be removed.

According to an embodiment of the circuit card configuration the card element is arranged to support an electric filter configuration.

### BRIEF DESCRIPTION OF THE DRAWINGS

A better understanding of the present invention will be had upon the reference to the following detailed description when read in conjunction with the accompanying drawings, wherein like reference characters refer to like parts throughout the several views, and in which:

FIG. 1a schematically illustrates a plan view of a circuit card configuration according to an embodiment of the present invention;

FIG. 1b schematically illustrates a cross sectional view A-A of the circuit card configuration in FIG. 1a;

FIG. 2a schematically illustrates a perspective view viewed obliquely from above of the circuit card configuration in FIG. 1a;

FIG. 2b schematically illustrates a perspective view viewed obliquely from below of the circuit card configuration in FIG. 1a; and

FIG. 3 schematically illustrates a perspective view viewed obliquely from above of a part of the circuit card configuration in FIG. 1a.

### DETAILED DESCRIPTION

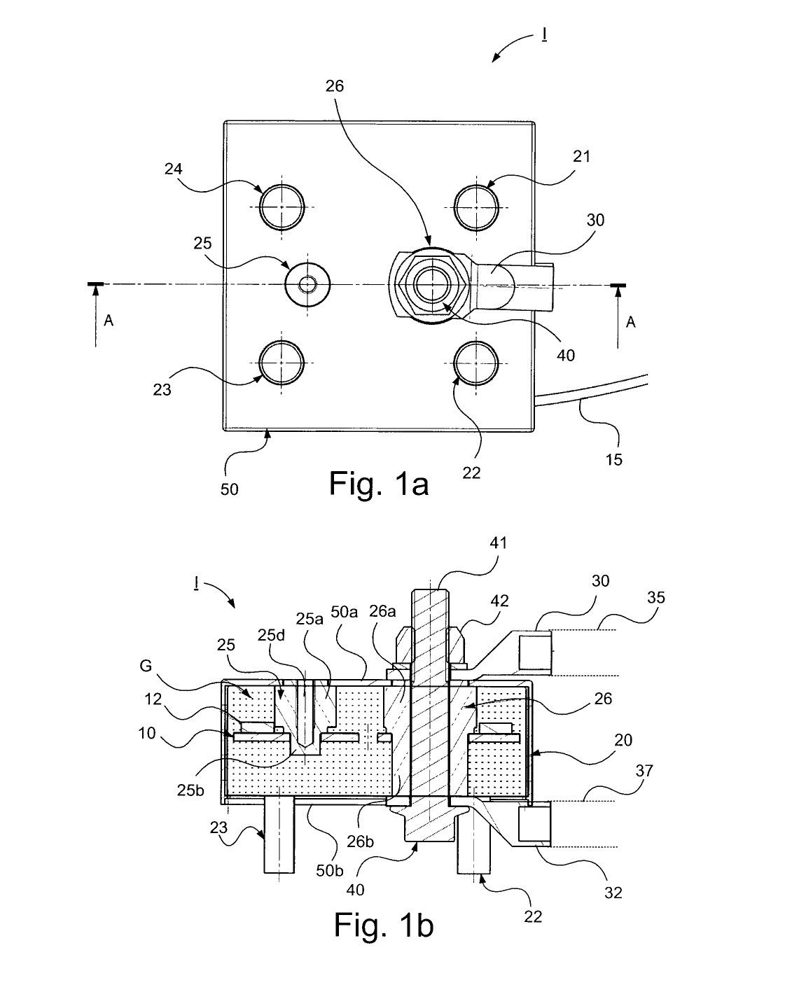

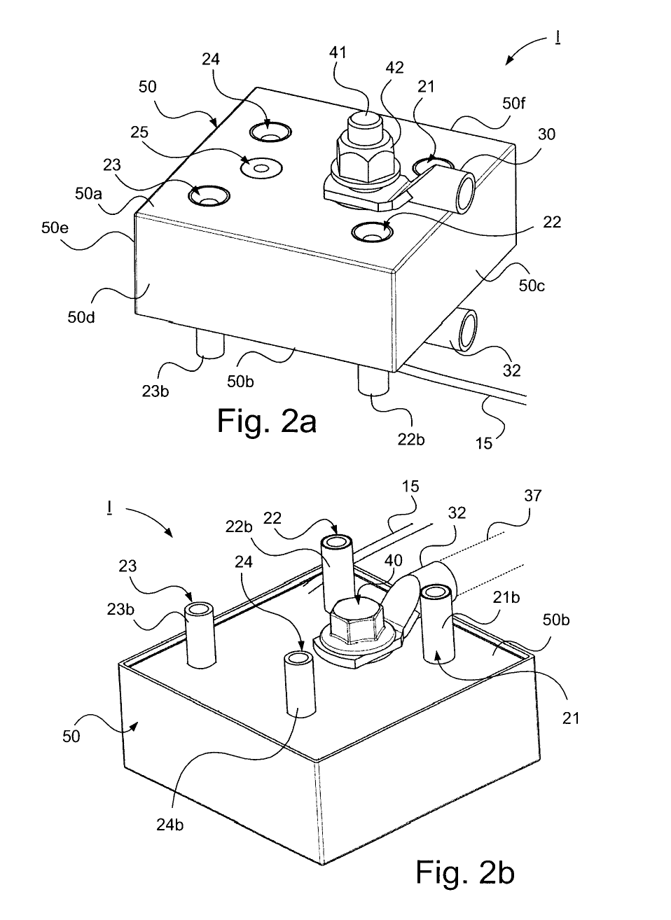

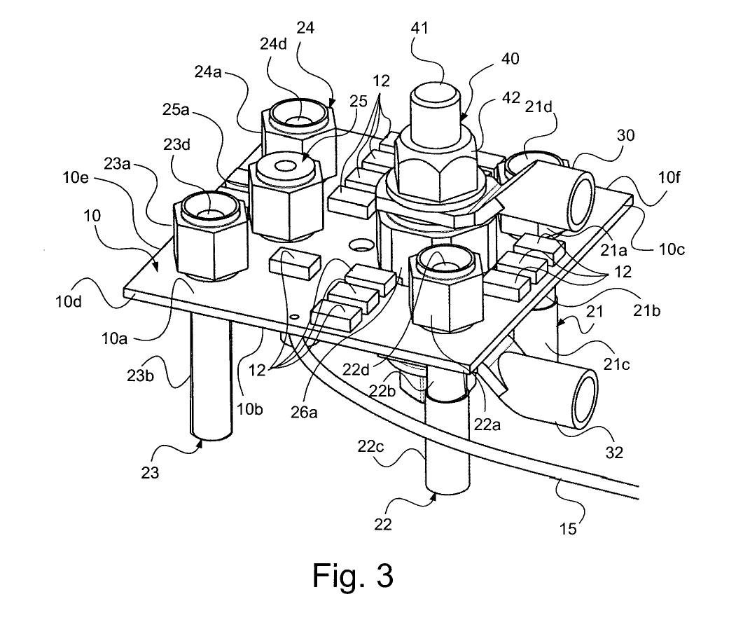

FIG. 1a-b and FIG. 2a-b schematically illustrates different views of a circuit card configuration I according to an embodiment of the present invention; and FIG. 3 schematically illustrates a perspective view viewed obliquely from above of a part of the circuit card configuration I in FIG. 1a without the actual casing/box and/or without protection compound.

The circuit card configuration I comprises a card element 10. The circuit card configuration I further comprises assembly points at which the card element 10 is arranged to be attached. The circuit card configuration I comprises electric components 12 arranged on the card element, which electric components may be constituted by any suitable components such as capacitors, inductors (coils), ferrites, diodes and other semiconductors, resistors, varistor and other transient and overvoltage protection components. The circuit configuration I comprises a signal cable 15 for current with signal being filtered, which cable 15 is electrically connected to the card element 10.

The circuit card configuration I comprises metallic bushings 21, 22, 23, 24, 25, 26 fixedly arranged at the card element 10. Said metallic bushings 21, 22, 23, 24, 25, 26 are according to an embodiment arranged to be directly attached to the card element 10 by means of soldered joints. Said metallic bushings 21, 22, 23, 24, 25, 26 are according to an embodiment arranged to be directly attached to the card element 10 by means of screw joints. Said metallic bushings 21, 22, 23, 24, 25, 26 are according to an embodiment arranged to be directly attached to the card element 10 by means of soldered joints and/or screw joints.

According to an embodiment said metallic bushings 21, 22, 23, 24, 25, 26 are turned. According to an embodiment said metallic bushings 21, 22, 23, 24, 25, 26 are essentially made of brass.

According to an embodiment one or more of said metallic bushings 21, 22, 23, 24, 25, 26 comprise an internal thread.

According to an embodiment said metallic bushings 21, 22, 23, 24, 25, 26 comprises a portion 21a, 22a, 23a, 24a, 25a, 26a with a polygonal cross section. According to the embodiment illustrated in e.g. FIG. 3 said polygon is a regular hexagon.

According to an embodiment said metallic bushings 21, 22, 23, 24, 26 comprises a through hole for said assembly and/or signal connection.

The circuit card configuration I according to the embodiment illustrated in FIG. 1a, 1b, 2a, 2b and FIG. 3 comprises a set of metallic bushings 21, 22, 23, 24 comprising assembly points for assembly at an assembly ground, said assembly ground according to an embodiment being constituted by a vehicle chassis.

Said set of metallic bushings 21, 22, 23, 24 comprising assembly points comprises a first assembly bushing 21, a second assembly bushing 22, a third assembly bushing 23 and a fourth assembly bushing 24.

The card element 10 has according to the embodiment illustrated in FIG. 1a, 1b, 2a, 2b and FIG. 3 an essentially square shape with an upper side 10a, and underside 10b and four side edges 10c, 10d, 10e, 10f and consequently four corners.

Said first assembly bushing 21 is arranged in the area of a first corner of the card element 10, said second assembly bushing 22 is arranged in the area of a second corner of the card element 10, said third assembly bushing 23 is arranged in the area of a third corner of the card element 10 and said fourth assembly bushing 24 is arranged in the area of a fourth corner of the card element 10.

Said first, second, third and fourth assembly bushings 21, 22, 23, 24 are arranged to run through the card element 20 from the upper side 10a to the lower side 10b.

Said first, second, third and fourth assembly bushing 21, 22, 23, 24 have an upper portion 21a, 22a, 23a, 24a with a hexagonal cross section. Said upper portion 21a, 22a, 23a, 24a consequently has a hexagonal outer shape.

Said first, second, third and fourth assembly bushing 21, 22, 23, 24 are arranged to protrude from the underside 10b of the card element 10. Said first, second, third and fourth assembly bushing 21, 22, 23, 24 comprises an assembly portion 21b, 22b, 23b, 24b protruding from the underside. Said upper portion 21a, 22a, 23a, 24a has a larger circumference than said assembly portion 21b, 22b, 23b, 24b protruding from the underside.

The from the underside protruding assembly portion 21b, 22b of the first and second assembly bushing 21, 22 is in a lower portion surrounded by an isolation casing 21c, 22c, which according to a variant is constituted by an isolating shrinking tubing, the isolation casing being arranged to protect against short circuiting in case the cable clip 32 described below for any reason should be turned to the side.

Said first, second, third and fourth assembly bushings 21, 22, 23, 24 each has a through hole 21d, 22d, 23d, 24d. Said first, second, third and fourth assembly bushings 21, 22, 23, 24 are according to an embodiment arranged to be attached to the chassis by means of a screw joint, wherein according to a variant screws are arranged to be inserted through the through holes, preferably not being threaded, and attached in goods threaded holes in the ground/chassis, wherein the entire circuit card configuration hereby is kept in place.

Said first, second, third and fourth assembly bushings 21, 22, 23, 24 consequently further constitute ground connection through said connection with the chassis. Hereby the from the underside protruding assembly portions 21b, 22b, 23b, 24b of the first, second, third and fourth assembly bushings 21, 22, 23, 24 also constitute connection portions for ground connection, wherein low transient impedance is facilitated. Said first, second, third and fourth assembly bushings 21, 22, 23, 24 consequently have both an assembly function and a connecting function.

The circuit card configuration I according to the embodiment illustrated in FIG. 1a, 1b, 2a, 2b and FIG. 3 comprises a metallic bushing 25 for signal connection, wherein the cable 15 is connected to the signal connection bushing 25, the signal being arranged to go through the card element to the cable 15.

The signal connection bushing 25 is arranged to run across through the card element 10 from the upper side to the underside. Said signal connection bushing 25 has an upper portion 25a protruding from the upper side 10a of the card element and a lower portion 25b protruding from the underside 10b of the card element 10. Said signal connection bushing 25 has a blind hole 25d running from the end of the upper portion 25a with an internal threading for connection by means of screw joint of the cable clip connected to signal cable. The signal connection bushing 25 is connected to the signal cable 15, wherein the signal connection bushing and the signal cable 15 are adapted for signals with relatively low current strength.

The upper portion 25a of said signal connection bushing 25 has a hexagonal cross section. Said upper portion 25a consequently has a hexagonal outer shape. Said upper portion 25a has a larger circumference than said portion 25b protruding from the underside 10b.

The circuit card configuration I according to the embodiment illustrated in FIG. 1a, 1b, 2a, 2b and FIG. 3 comprises a metallic bushing 26 for connection of cable connected to cable clip 30, 32 for input and output signal, here called signal connection bushing 26.

The signal connection bushing 26 is arranged to run across through the card element 10 from the upper side to the underside. Said signal connection bushing has an upper portion 26a protruding from the upper side 10a of the card element 10 and a lower portion 26b protruding from the underside 10 of the card element 10. Said signal connection bushing 26 has a through hole 26d running from the end of the upper portion 26a for connection by means of a screw joint 40 of cable clip 30, 32 connected to signal cable 35, 37. According to this embodiment the screw joint 40 comprising a screw 41 is arranged to be screwed from the opening 26d of the lower portion 26b and through said through hole 26d such that the screw 41 projects through the opening of the upper portion 26a.

A cable clip 30 electrically conductively connected to a signal cable 35 is arranged to be connected in the upper portion 26a of the signal connection bushing 26 by means of a nut 42 of the screw joint 40. A cable clip 32 electrically conductively connected to a signal cable 37 is arranged to be connected in the lower portion 26b of the signal connection bushing 26 by means of a screw of the screw joint 42. Hereby one of said cables 35, 37 is arranged for input signal and the other for output signal. Said input and output signals are arranged to be filtered by means of the circuit card configuration. Said cables 35, 37 and signal connection bushing 26 are adapted for signals with high current strength relative to the cable 15 and signal connection bushing 25.

The upper portion 26a of said signal connection bushing 26 has a hexagonal cross section. Said upper portion 26a consequently has a hexagonal outer shape. Said upper portion 26a has a larger circumference than said lower portion protruding from the underside.

The circuit card configuration I according to an embodiment comprises a box 50. The box 50 has en upper side 50a and surrounding sides 50c, 50d, 50e, 50f. The box 50 is intended to receive from the upper side the card element 10 provided with bushings. The box is further arranged to house the card element 10 and at least portions of said bushings 21, 22, 23, 24, 25, 26. The box 50 is according to an embodiment made of a plastic material.

The upper side 50a of the box 50 has openings through which the upper portions 21a, 22a, 23a, 24a of said assembly bushings 21, 22, 23, 24 are arranged to protrude. Further the upper side of the box 50 has en opening arranged to surround said signal connection bushing 26, wherein said screw 41 of the screw joint 40 is arranged to project out through said opening by assembled cable clip 32 connected to signal cable. In addition the upper side 50a of the box 50 has an opening arranged to surround said signal connection bushing 25, wherein a screw of a screw joint, not shown, is arranged to project out through said opening at assembled cable clip connected to ground cable, not shown.

Insertion of said card element provided with said bushings 21, 22, 23, 24, 25, 26 is effected from underneath. Alternatively the upper side is open and the underside is closed wherein the card element 10 provide with bushings 21, 22, 23, 24, 25, 26 is arranged to be inserted into said box 50 from above.

According to an embodiment apparent from FIG. 1b the card element 10 with bushings 21, 22, 23, 24, 25, 26 is arranged to be embedded in a cast compound G, the cast compound being electrically isolating, and preferably water resistant, having good adhesitivity and high structural strength without being entirely inelastic such that certain flexibility is permitted but rigid enough to keep the construction, i.e. the card element 10 provided with bushings 21, 22, 23, 24, 25, 26, together when it is hardened. The cast compound is according to a variant constituted by so called Sytcast U 2500.

The stiffened cast compound G in the box 50 forms in the bottom an underside 50b of the box 50. The underside 50b of the box 50 has opening through which the assembly portions 21b, 22b, 23b, 24b of said assembly bushings 21, 22, 23, 24 are arranged to project. Further the underside 50b of the box 50 has en opening arranged to surround said signal connection bushing 26, wherein said screw 41 of the screw joint 40 is arranged to project through said opening at assembled cable clip 30 connected to signal cable.

Said cast compound G is arranged to be inserted after the card element provided with bushings 21, 22, 23, 24, 25, 26 has been inserted into the box 50 from underneath, wherein the cast compounds allowed to be filled through an opening in the card element and opening between the walls 50c, 50d, 50e, 50f of the box and the card element 10. According to a variant said cast compound G is inserted prior to the card element 10 provided with bushings 21, 22, 23, 24, 25, is inserted into the box 50.

By the cast compound G the vibration durability is improved. Due to the box 50 and the cast compound G a robust construction of the circuit card configuration I with high structural strength is obtained.

According to a variant the circuit card configuration I has no cast compound, wherein the card element is varnished with varnish suitable for the purpose for protecting components and soldered joints from moist and corrosion. Hereby the weight of the circuit card configuration is reduced in comparison to circuit card configuration with cast compound. Hereby the card element 10 provided with bushings 21, 22, 23, 24, 25, 26 is inserted into said box 50 from underneath, wherein a separate underside 50b being sealingly applied, the underside having openings for protruding portions of the bushings.

Alternatively the card element with bushings is inserted from above wherein the upper side 50a constitutes a separate upper side being sealingly applied.

According to an alternative variant said box 50 is constituted by a mould wherein the box 50 shaped as a mould is removed after the cast compound G has stiffened about the card element 10 provided with bushings 21, 22, 23, 24, 25, 26 such that the stiffened cast compound G constitutes both outer protection and improves the structural strength.

As the bushings 21, 22, 23, 24, 25, 26, here the upper portion 21a, 22a, 23a, 24a, 25a, 26a of the respective bushing has a hexagonal cross section the bushing gets a good hold in the cast compound G since the bushings are prevented from being turned. According to a variant the bushings are made from hexagonal elements where the portions 21b, 22b, 23b, 24b, 25b, 26b are provided through turning. Further the soldered seam is protected by the hexagonal portions in the case the respective bushing is attached with soldered seam.

According to an embodiment the card element 10 is arranged to support an electric filter configuration. The circuit configuration I according to this variant consequently comprises a filter configuration.

Above a circuit card configuration I according to the present invention has been described in connection to FIG. 1a, 1b, 2a, 2b and FIG. 3 comprising a card element 10 arranged to be attached via assembly points comprising metallic bushing 21, 22, 23, 24, 25, 26 and where said card element 10 is arranged to by means of metallic bushing 21, 22, 23, 24, 25, 26 support connection points for signal connection and ground connection. Hereby the respective assembly points as well as the respective connection points comprise at least one metallic bushing 21, 22, 23, 24. The respective bushing 21, 22, 23, 24, 25, 26 may consequently be used as assembly point for attaching the circuit configuration I e.g. to a chassis and/or as connection point for signal connection or ground connection.

A circuit card configuration I according to the present invention may advantageously be used for all circuit card assembled electronics where thick cables, e.g. cable with a thickness of 5 mm or more where bushings are required, where thick cables are required for high current strengths. The circuit card configuration may further advantageously be used where good ground connection and environmental durability is required, that do not need to be screened. For example the circuit card configuration I may be comprised/constituted by a filter configuration with a frequency of up to 30 MHz. The circuit card configuration I is also usable for current shunts, connectors or the like.

The foregoing description of the preferred embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated.

1. A circuit card configuration comprising a card element being arranged to be attached via assembly points and to support connection points for signal connection and ground connection, characterized in that the respective assembly points as well as the respective connection points comprise a metallic bushing arranged to be attached at the card element.

2. A circuit card configuration according to claim 1, wherein said metallic bushing is essentially made of brass.

3. A circuit card configuration according to claim 1, wherein the card element with its bushings is arranged to be embedded in a cast compound.

4. A circuit card configuration according to claim 1, wherein said metallic bushing comprises an internal thread.

5. A circuit card configuration according to claim 1, wherein said metallic bushing comprises a portion with a polygonal cross section.

6. A circuit card configuration according to claim 1, wherein said polygon is a regular hexagon.

7. A circuit card configuration according to claim 1, wherein said bushings is arranged to be attached to the card element with soldered joints and or screw joints.

8. A circuit card configuration according to claim 1, wherein said metallic bushing comprises a through hole for said assembly and/or signal connection.

9. A circuit card configuration according to claim 1, wherein said card element and at least parts of said bushings are housed in a box.

10. A circuit card configuration according to claim 1, wherein the card element is arranged to support an electric filter configuration.
